(19) United States
(12) Patent Application Publication
(10) Pub. No.: US 2019/0154305 A1
(43) Pub. Date: May 23, 2019

(54) APPARATUSES, SYSTEMS, AND METHODS FOR A SELF-BALANCED PHOTOVOLTAIC SYSTEM

(71) Applicant: Quest Renewables, LLC, Atlanta, GA (US)

(72) Inventors: Joseph N. Goodman, Snowmass Village, CO (US); James Keane, Atlanta, GA (US)

(21) Appl. No.: 16/191,189

(22) Filed: Nov. 14, 2018

Related U.S. Application Data
(60) Provisional application No. 62/585,841, filed on Nov. 14, 2017.

(51) Int. Cl. F24S 25/63; H02S 20/30; H01L 31/0475; F24S 25/20

(52) U.S. Cl. CPC F24S 25/63; F24S 25/20; H01L 31/0475; H02S 20/30

(57) ABSTRACT

Apparatuses, systems, and methods for a self-balanced PV array that can withstand extreme loads (e.g., wind, snow, etc.) applied across large surface areas using one or more supports configured along just a single axis. Generally, the load balancing mechanism comprises, in one embodiment, a configuration of support struts that are attached to the PV array at various points depending on the configuration of the PV array and the expected loads. The struts are generally configured to provide two work points that are distributed above and below the ground, pedestal or other connection of the PV array to the surface condition.

### CROSS REFERENCE TO RELATED APPLICATIONS

This application claims priority to, the benefit under 35 U.S.C. § 119 of, and incorporates by reference herein in its entirety U.S. Provisional Patent Application No. 62/585,841, filed Nov. 14, 2017, and entitled “Apparatuses, Systems, and Methods for a Self-Balanced Photovoltaic System.”

### TECHNICAL FIELD

The present apparatuses, systems, and methods relate generally to photovoltaic arrays and, more particularly, to deployment of a planar photovoltaic array that is balanced through structural autonomy.

### BACKGROUND

Current photovoltaic (“PV”) systems have a low power density of 10-20 watts per square foot, with the maximum theoretical power density only 2-5 times more dense. In contrast, commercial buildings and other users of electricity require many thousand or even millions of watts per hour. As a result, modern PV systems entail surface areas that total in the hundreds to millions of square feet to collect useful amounts of solar energy for commercial, industrial, or utility applications.

Generally, all of this PV surface area that is exposed to the sun is similarly exposed to wind and snow loads that are also proportional to the surface area. Depending on the structural system, the wind and snow loads result in compressive and tensile forces, internal moments, and overturning moments. These forces and moments are a major driver of PV system deployment cost and time, effectively limiting the extent to which PV systems can be economically deployed. Currently, most PV systems rely on frequent moment resisting piers or paired restraints with axial only loads that eliminate structural moments, both of which are material intensive to resolve and require supports to be placed frequently both along and across a PV array. Generally, where a single support is utilized in the across direction of a PV array, it is because the array length is minimal in that dimension. Overall, these systems are extremely limited in their ability to integrate into spaces with primary uses unrelated to energy generation (e.g., parking lots, playgrounds, farms, etc.) because they require a large number of supports that must be placed in very specific locations.

Therefore, there is a long-felt but unresolved need for a system that is self-balanced through structural autonomy thereby requiring fewer supports for more efficient integration into existing spaces and less disturbance of existing land profiles.

### BRIEF SUMMARY OF THE DISCLOSURE

Briefly described, and according to one embodiment, aspects of the present disclosure generally relate to apparatuses, systems, and methods for a self-balanced PV array.

In various embodiments, the self-balanced PV array can withstand extreme loads (e.g., wind, snow, etc.) applied across large surface areas using one or more supports configured along just a single axis. More specifically, the loads that are effectively resisted generally include all combinations of balanced and unbalanced uplift and downforce and lateral loads. The load balancing mechanism comprises, in one embodiment, a configuration of support struts (e.g., upper chord and lower chord struts) that are attached to the PV array at various points depending on the configuration of the PV array and the expected loads. The struts are generally configured to provide two work points that are distributed above and below the ground, pedestal or other connection of the PV array to the surface condition. The vertical separation of the work points is of the same order of magnitude as the lever arm (e.g., portion of the PV array extending past the base that will need to be balanced) that will experience unbalanced loads, which provides material efficient resistance to overturning moments based on the geometry instead of the strength of the materials (that would otherwise be heavy and cost prohibitive).

The presently disclosed self-balanced PV array, in various embodiments, generally allows for the overturning moment of a large PV array to be balanced on a single support rather than requiring multiple supports or small PV arrays that use one support but can only provide moment resistance for approximately 20-30% of the PV array collection surface.

In one embodiment, a self-balanced photovoltaic system, comprising: one or more photovoltaic arrays; and a photovoltaic array support structure comprising an upper portion and a lower portion, wherein the one or more photovoltaic arrays are affixed to the upper portion and wherein the photovoltaic array support structure is operably connected to a surface condition by two or more upper struts that are affixed to the upper portion and two or more lower struts that are affixed to the lower portion.

In one embodiment, a method of installing a self-balanced photovoltaic system, comprising the steps of: assembling a photovoltaic array support structure comprising an upper portion and a lower portion; affixing one or more photovoltaic arrays to the upper portion; affixing two or more upper struts to the upper portion and to a surface condition; and affixing two or more lower struts to the lower portion and to the surface condition.

According to one aspect of the present disclosure, the system, wherein the two or more upper struts comprise an upper strut work point and wherein the two or more lower struts comprise a lower strut work point. Furthermore, the system, wherein the upper strut work point is between the lower portion and the surface condition and wherein the surface condition is between the upper strut work point and the lower strut work point. Moreover, the system, wherein the upper strut work point is above the surface condition and wherein the lower strut work point is below the surface condition. Further, the system, wherein the two or more upper struts are affixed across the surface condition such that the two or more upper struts cross above the surface condition. Additionally, the system, wherein the upper strut work point is located where the two or more upper struts cross above the surface condition. Also, the system, wherein the two or more lower struts are affixed on opposite sides of the surface condition such that the two or more lower struts do not cross above the surface condition but would cross below the surface condition if the two or more lower struts extended below the surface condition. In addition, the system, wherein the lower strut work point is located where the two or more lower struts would cross below the surface condition if the two or more lower struts extended below the surface condition.

According to one aspect of the present disclosure, the system, wherein the ability of the system to resist uplift or downforce on the one or more photovoltaic arrays depends on a distance between the upper strut work point and the lower work point such that the greater the distance, the greater the ability of the system to resist uplift or downforce. Furthermore, the system, wherein the distance exceeds 1 foot. Moreover, the system, wherein the distance exceeds 3 feet. Further, the system, wherein the uplift is generated by wind and the downforce is generated by snow. Additionally, the system, wherein the photovoltaic array support structure comprises a truss comprising two upper chords in the upper portion and one lower chord in the lower portion affixed by a plurality of struts, wherein the two or more upper struts comprise two or more upper chord struts that are each affixed to one of the two upper chords and the two or more lower struts comprise two or more lower chord struts that are affixed to the lower chord. Also, the system, wherein the surface condition comprises a pedestal, a building, a parking lot, or a parking garage. In addition, the system, wherein the two or more upper struts are affixed to the upper portion and the two or more lower struts are affixed to the lower portion by pin connections.

According to one aspect of the present disclosure, the method, wherein the two or more upper struts comprise an upper strut work point and wherein the two or more lower struts comprise a lower strut work point. Furthermore, the method, wherein the two or more upper struts are affixed across the surface condition such that the two or more upper struts cross above the surface condition. Moreover, the method, wherein the two or more lower struts are affixed on opposite sides of the surface condition such that the two or more lower struts do not cross above the surface condition but would cross below the surface condition if the two or more lower struts extended below the surface condition. Further, the method, wherein the upper strut work point is located where the two or more upper struts cross above the surface condition and wherein the lower strut work point is located where the two or more lower struts would cross below the surface condition if the two or more lower struts extended below the surface condition.

These and other aspects, features, and benefits of the claimed invention(s) will become apparent from the following detailed written description of the preferred embodiments and aspects taken in conjunction with the following drawings, although variations and modifications thereto may be effected without departing from the spirit and scope of the novel concepts of the disclosure.

### BRIEF DESCRIPTION OF THE DRAWINGS

The accompanying drawings illustrate one or more embodiments and/or aspects of the disclosure and, together with the written description, serve to explain the principles of the disclosure. Wherever possible, the same reference numbers are used throughout the drawings to refer to the same or like elements of an embodiment, and wherein:

FIG. 1 illustrates an exemplary self-balanced PV system according to one embodiment of the present disclosure.

FIG. 2 illustrates an exemplary system load case according to one embodiment of the present disclosure.

### DETAILED DESCRIPTION

For the purpose of promoting an understanding of the principles of the present disclosure, reference will now be made to the embodiments illustrated in the drawings and specific language will be used to describe the same. It will, nevertheless, be understood that no limitation of the scope of the disclosure is thereby intended; any alterations and further modifications of the described or illustrated embodiments, and any further applications of the principles of the disclosure as illustrated therein are contemplated as would normally occur to one skilled in the art to which the disclosure relates. All limitations of scope should be determined in accordance with and as expressed in the claims.

Whether a term is capitalized is not considered definitive or limiting of the meaning of a term. As used in this document, a capitalized term shall have the same meaning as an uncapitalized term, unless the context of the usage specifically indicates that a more restrictive meaning for the capitalized term is intended. However, the capitalization or lack thereof within the remainder of this document is not intended to be necessarily limiting unless the context clearly indicates that such limitation is intended.

### Overview

Aspects of the present disclosure generally relate to apparatuses, systems, and methods for a self-balanced PV array.

In various embodiments, the self-balanced PV array can withstand extreme loads (e.g., wind, snow, etc.) applied across large surface areas using one or more supports configured along just a single axis. More specifically, the loads that are effectively resisted generally include all combinations of balanced and unbalanced uplift and downforce and lateral loads. The load balancing mechanism comprises, in one embodiment, a configuration of support struts (e.g., upper chord and lower chord struts) that are attached to the PV array at various points depending on the configuration of the PV array and the expected loads. The struts are generally configured to provide two work points that are distributed above and below the ground, pedestal or other connection of the PV array to the surface condition. The vertical separation of the work points is of the same order of magnitude as the lever arm (e.g., portion of the PV array extending past the base that will need to be balanced) that will experience unbalanced loads, which provides material efficient resistance to overturning moments based on the geometry instead of the strength of the materials (that would otherwise be heavy and cost prohibitive).

The presently disclosed self-balanced PV array, in various embodiments, generally allows for the overturning moment of a large PV array to be balanced on a single support rather than requiring multiple supports or small PV arrays that use one support but can only provide moment resistance for approximately 20-30% of the PV array collection surface.

### Exemplary Embodiments

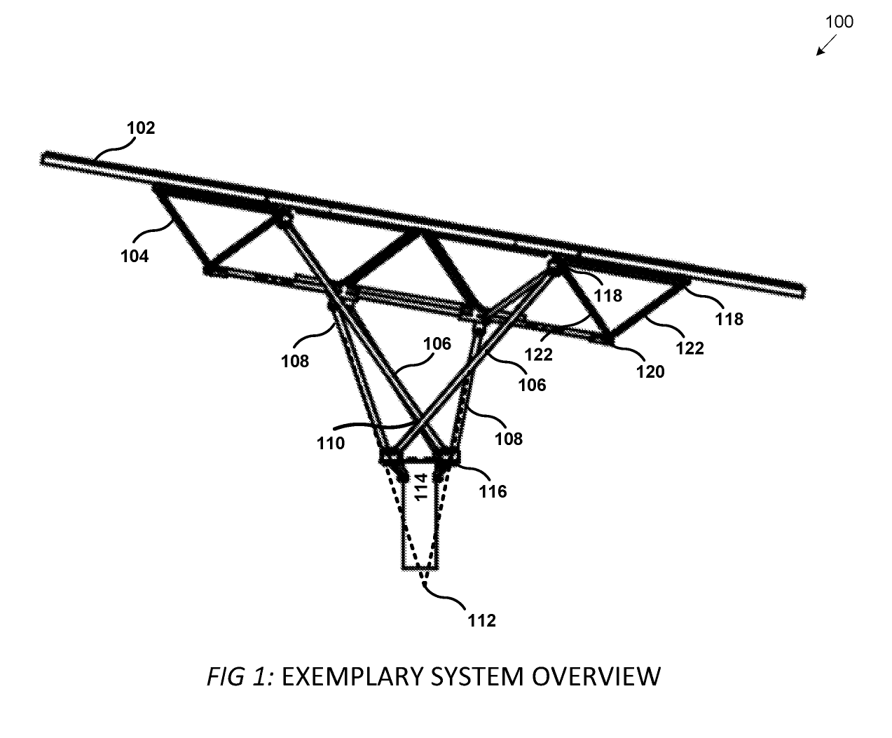

Referring now to the figures, for the purposes of example and explanation of the fundamental processes and components of the disclosed apparatuses, systems, and methods, reference is made to FIG. 1, which illustrates an exemplary, high-level overview of one embodiment of the self-balanced PV system 100. As will be understood and appreciated, the exemplary self-balanced PV system 100 shown in FIG. 1 represents merely one approach or embodiment of the present disclosure, and other aspects are used according to various embodiments of the present disclosure. Generally, this system 100 is highly differentiated for its ability to balance a large surface area PV array over a single row (of one or more) pedestals 114 without risk of tipping over.

In various embodiments, the self-balanced PV system 100 comprises one or more PV arrays 102 (e.g., one or more PV modules, also referred to as “solar panels”) that are supported by at least one PV truss 104 (also referred to as a “space frame” or “PV array support structure”), wherein each PV truss 104 is connected to the surface condition 114 (e.g., ground, pedestal, or other support structure) via one or more upper chord struts 106 and lower chord struts 108. Both upper chord struts 106 and lower chord struts 108 transfer axial loads from the PV arrays 102 (e.g., from wind, snow, animals, debris, etc.) along the center of each strut's 106, 108 mass. In one embodiment, the upper chord struts 106 (also referred to herein as “upper struts”) are affixed to the top portion of the PV array support structure 104. In one embodiment, the lower chord struts 108 (also referred to herein as “lower struts”) are affixed to the bottom portion of the PV array support structure 104. For example, in one embodiment, wherein the PV array support structure 104 comprises one or more trusses comprising two upper chords 118 and one lower chord 120 (the chords 118 and 120 connected via multiple struts 122), the upper chord struts 106 are affixed to the upper chord 118 and the lower chord struts 108 are affixed to the lower chord 120. Generally, this disclosure places no limitation on the type of PV array 102 or PV array support structure 104 that is compatible with the system 100. For example, in one embodiment, wherein the PV array 102 is affixed directly to the upper chords 118, the upper chord struts 106 may also be affixed directly to the PV array 102.

Generally, the center of mass of the upper chord struts 106 transfers the axial forces experienced by the PV array 102 to an upper chord strut work point 110, which is, in one embodiment, the point of convergence of the upper chord struts 106. In an alternate embodiment, the upper chord strut work point 110 may be the center of mass of the upper chord struts 106 (which may be intentionally modified to change the location of the upper chord strut work point 110 by increasing/decreasing the mass of the top half of the upper chord struts 106 in comparison to the bottom half; e.g., using a rod of decreasing thickness, adding weights, etc.). Similarly, in one embodiment, the center of mass of the lower chord struts 108 also transfers the axial forces experienced by the PV array 102 to a lower chord strut work point 112, which is generally below the connections of the lower chord struts 108 at the point where the lower chord struts 108 would converge if the lower chord struts 108 extended that far (generally represented by dotted lines in FIG. 1). Taken together, the upper chord strut work point 110 and the lower chord strut work point 112 are generally separated over a large vertical distance (e.g., multiple feet, multiple yards, etc.) with one above the surface condition and one below the surface condition 114. In various embodiments, the distance between the upper chord strut work point 110 and the lower chord strut work point 112 depends directly on the anticipated loads for the system 100, with the distance increasing as the anticipated loads increase. Accordingly, the system 100 may be designed to resist a specific load by manipulating the distance between the upper chord strut work point 110 and the lower chord strut work point 112.

In one embodiment, the force is generally transferred from the struts 106, 108 to the pedestal 114 at the location where the struts' 106, 108 center of mass converges with the pedestal's center of mass. The pedestal 114, in various embodiments, comprises a baseplate 116 to support and attach the upper chord struts 106 and lower chord struts 108 with a pin connection that allows rotation of the struts 106, 108 about the pin without translation. In an alternate embodiment, the upper chord struts 106 and lower chord struts 108 are affixed via welding, a bolt, or other fastening mechanism. Taken together, the upper chord strut work point 110 and the lower chord strut work point 112 are generally separated over a large distance (e.g., multiple feet, multiple yards, etc.) with one above the baseplate 116 and one below the baseplate 116. In various embodiments, the upper chord struts 106 are pinned across the baseplate 116 such that the upper chord struts 106 cross at a location above the baseplate 116. As a result, the upper chord strut work point 110 is generally located above the baseplate 116. In various embodiments, the lower chord struts 108 on opposite edges of the baseplate 116 without crossing such that the projection of the lower chord struts' 108 center of mass (generally represented by a dotted line in FIG. 1) converges with the pedestal's center of mass below the baseplate 116. As a result, the lower chord struts work point 112 is generally located below the baseplate 116.

As will be understood by one having ordinary skill in the art, this disclosure places no limitations on the materials from the struts 106 and 108 are made (e.g., steel, iron, aluminum, other metal with sufficient structural integrity, etc.). Equally, the present disclosure places no limitations on the materials from which the other parts of the system 100 may be made, assuming the materials have sufficient structural durability for their intended purposes (as described herein).

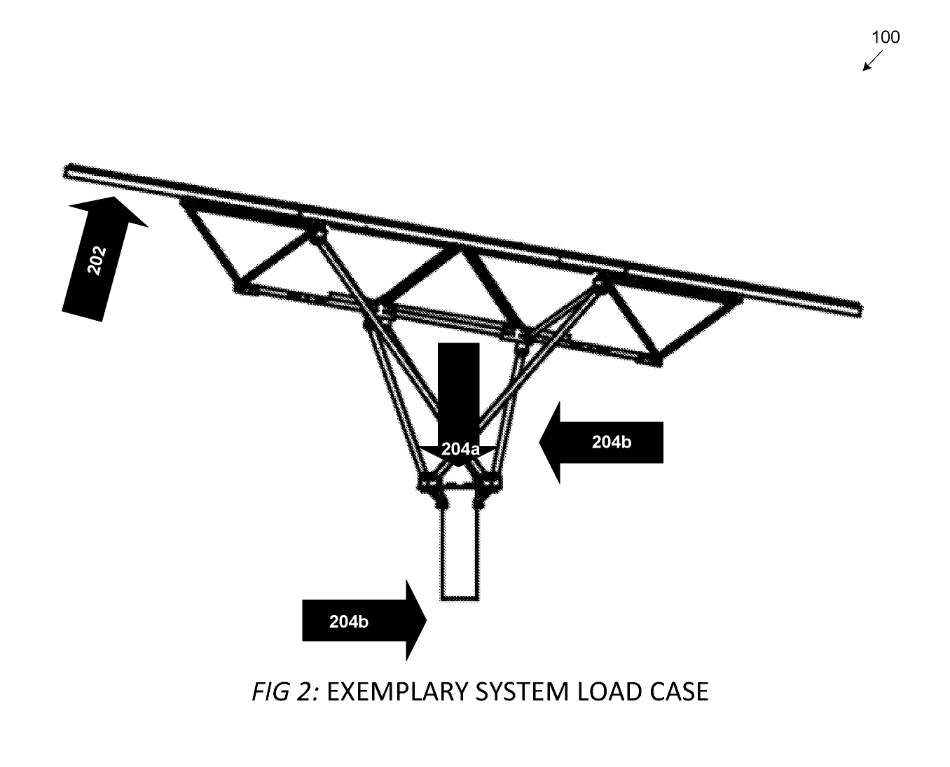

Referring now to FIG. 2, a representative load case (unbalanced uplift 202 and the associated balancing reactions 204) on the system 100 (although many of the reference characters of FIG. 1 are not shown in FIG. 2, the system 100 should be understood to be the same in both figures) is shown according to one embodiment of the present disclosure. As shown, the balancing reactions comprise a downforce 204a and a moment couple 204b at the work points 110, 112. Self-balance in the system 100 is achieved, in various embodiments, by imparting a moment couple 204b at the pair of work points 110, 112 with orientation that counters the rotation imparted by the unbalanced load 202. In one embodiment, an unbalanced uplift load 202 imparts a clockwise rotation on the system 100, which is reacted with a moment couple 204a at the work points 110, 112 that imparts balancing counter-clockwise rotation. In various embodiments, the configuration of the upper chord struts 106 and lower chord struts 108 generates different moment couples 204b depending on the load 202 placed on the system 100 (e.g., a load 202 that imparts counterclockwise rotation would result in a moment couple 204b that generates clockwise rotation, etc.).

Generally, the large distance over which the couple reaction 204b occurs enables resistance of the load with low stresses and correspondingly low material requirements (e.g., only the struts 106, 108, instead of multiple piers 114 or other surface conditions) that translate into additional system benefits, including lower labor costs, high connection reliability, decreased surface condition footprint, and lower overall cost. By orienting the struts 106 and 108 such that their work points 110 and 112 are separated over a large distance and such that their center of mass converges with the center of mass of the pedestal 114, the system 100 is self-balancing.

The foregoing description of the exemplary embodiments has been presented only for the purposes of illustration and description and is not intended to be exhaustive or to limit the inventions to the precise forms disclosed. Many modifications and variations are possible in light of the above teaching. While various aspects have been described in the context of a preferred embodiment, additional aspects, features, and methodologies of the claimed inventions will be readily discernible from the description herein, by those of ordinary skill in the art. Many embodiments and adaptations of the disclosure and claimed inventions other than those herein described, as well as many variations, modifications, and equivalent arrangements and methodologies, will be apparent from or reasonably suggested by the disclosure and the foregoing description thereof, without departing from the substance or scope of the claims. Furthermore, any sequence(s) and/or temporal order of steps of various processes described and claimed herein are those considered to be the best mode contemplated for carrying out the claimed inventions. It should also be understood that, although steps of various processes may be shown and described as being in a preferred sequence or temporal order, the steps of any such processes are not limited to being carried out in any particular sequence or order, absent a specific indication of such to achieve a particular intended result. In most cases, the steps of such processes may be carried out in a variety of different sequences and orders, while still falling within the scope of the claimed inventions. In addition, some steps may be carried out simultaneously, contemporaneously, or in synchronization with other steps.

The embodiments were chosen and described in order to explain the principles of the inventions and their practical application so as to enable others skilled in the art to utilize the inventions and various embodiments and with various modifications as are suited to the particular use contemplated. Alternative embodiments will become apparent to those skilled in the art to which the claimed inventions pertain without departing from their spirit and scope. Accordingly, the scope of the claimed inventions is defined by the appended claims rather than the foregoing description and the exemplary embodiments described therein.

What is claimed is:

1. A self-balanced photovoltaic system, comprising:
one or more photovoltaic arrays; and
a photovoltaic array support structure comprising an upper portion and a lower portion, wherein the one or more photovoltaic arrays are affixed to the upper portion and wherein the photovoltaic array support structure is operably connected to a surface condition by two or more upper struts that are affixed to the upper portion and two or more lower struts that are affixed to the lower portion.

2. The system of claim 1, wherein the two or more upper struts comprise an upper strut work point and wherein the two or more lower struts comprise a lower strut work point.

3. The system of claim 2, wherein the upper strut work point is between the lower portion and the surface condition and wherein the surface condition is between the upper strut work point and the lower strut work point.

4. The system of claim 2, wherein the upper strut work point is above the surface condition and wherein the lower strut work point is below the surface condition.

5. The system of claim 2, wherein the two or more upper struts are affixed across the surface condition such that the two or more upper struts cross above the surface condition.

6. The system of claim 5, wherein the upper strut work point is located where the two or more upper struts cross above the surface condition.

7. The system of claim 2, wherein the two or more lower struts are affixed on opposite sides of the surface condition such that the two or more lower struts do not cross above the surface condition but would cross below the surface condition if the two or more lower struts extended below the surface condition.

8. The system of claim 7, wherein the lower strut work point is located where the two or more lower struts would cross below the surface condition if the two or more lower struts extended below the surface condition.

9. The system of claim 2, wherein the ability of the system to resist uplift or downforce on the one or more photovoltaic arrays depends on a distance between the upper strut work point and the lower work point such that the greater the distance, the greater the ability of the system to resist uplift or downforce.

10. The system of claim 9, wherein the distance exceeds 1 foot.

11. The system of claim 10, wherein the distance exceeds 3 feet.

12. The system of claim 11, wherein the uplift is generated by wind and the downforce is generated by snow.

13. The system of claim 1, wherein the photovoltaic array support structure comprises a truss comprising two upper chords in the upper portion and one lower chord in the lower portion affixed by a plurality of struts, wherein the two or more upper struts comprise two or more upper chord struts that are each affixed to one of the two upper chords and the two or more lower struts comprise two or more lower chord struts that are affixed to the lower chord.

14. The system of claim 1, wherein the surface condition comprises a pedestal, a building, a parking lot, or a parking garage.

15. The system of claim 1, wherein the two or more upper struts are affixed to the upper portion and the two or more lower struts are affixed to the lower portion by pin connections.

16. A method of installing a self-balanced photovoltaic system, comprising the steps of:
assembling a photovoltaic array support structure comprising an upper portion and a lower portion;
affixing one or more photovoltaic arrays to the upper portion;
affixing two or more upper struts to the upper portion and to a surface condition; and
affixing two or more lower struts to the lower portion and to the surface condition.

17. The method of claim 16, wherein the two or more upper struts comprise an upper strut work point and wherein the two or more lower struts comprise a lower strut work point.

18. The method of claim 17, wherein the two or more upper struts are affixed across the surface condition such that the two or more upper struts cross above the surface condition.

19. The method of claim 18, wherein the two or more lower struts are affixed on opposite sides of the surface condition such that the two or more lower struts do not cross above the surface condition but would cross below the surface condition if the two or more lower struts extended below the surface condition.

20. The method of claim 19, wherein the upper strut work point is located where the two or more upper struts cross above the surface condition and wherein the lower strut work point is located where the two or more lower struts would cross below the surface condition if the two or more lower struts extended below the surface condition.
